(19) United States
(12) Patent Application Publication
(10) Pub. No.: US 2021/0400818 A1
(43) Pub. Date: Dec. 23, 2021

(54) CIRCUIT BOARD AND MANUFACTURING METHOD THEREOF

(71) Applicant: HUIZHOU GLORYSKY ELECTRONICS CO.,LTD, Huizhou (CN)

(72) Inventors: Xiaobin Xu, Huizhou (CN); Yong Shao, Huizhou (CN); jinxing Chen, Huizhou (CN)

(21) Appl. No.: 17/447,058

(22) Filed: Sep. 7, 2021

(30) Foreign Application Priority Data
Oct. 29, 2020 (CN) 20201118330.0

(51) Int. Cl. H05K 3/18; H05K 3/00

(52) U.S. Cl. CPC H05K 3/185; H05K 3/025; H05K 3/0047; H05K 3/188

(57) ABSTRACT

The present disclosure discloses a circuit board and a manufacturing method thereof. The manufacturing method of the circuit board comprises: forming an electroplated coating on a board body of the circuit board; performing image transfer on the board body; drilling the board body after image transfer to remove a copper layer, adjacent to the two sides of a gold finger, on the circuit board, thereby forming a strip; performing forward and reverse routing towards directions away from each other respectively at the two sides of each gold finger to form a first routing tape and a second routing tape, wherein the first routing tape and the second routing tape are connected to the two ends of the strip respectively; and removing burrs on a surface of the board body through an etching process.

### TECHNICAL FIELD

The present disclosure relates to the technical field of production of circuit boards, in particular to a circuit board and a manufacturing method thereof.

### BACKGROUND

One end of a circuit board is inserted into a slot of a connector to electrically connect with the outside through plug pins in the slot of the connector, and thus the circuit board is in communication connection with the outside. Specifically, a bonding pad or a copper sheet or a metal coating is arranged on the circuit board to make the circuit board be in contact conduction with the plug pins at corresponding positions, and then the circuit board is electrically connected with the connector. Therefore, the bonding pad is manufactured on the circuit board, or the copper sheet is plated on the circuit board, or metal is plated on the circuit board, wherein a structure plated with the metal at the corresponding position of the circuit board is called a gold finger of the circuit board.

However, due to the factors such as non-optimal design size of the gold finger and unreasonable selection of a router bit, in the process of machining and forming a metal plated edge of the gold finger on the circuit board, i.e., in the process of feeding, the copper sheet on the circuit board is rolled up, the problem that the copper sheet on the circuit board is warped in the process of machining a gold finger area exists, thus the gold finger is poor in wear resistance, and meanwhile, the gold finger is poor in conductive property.

### SUMMARY

The present disclosure aims to overcome disadvantages in the prior art, and provides a circuit board having a gold finger with better wear resistance and better conductive property, and a manufacturing method of the circuit board.

The purpose of the present disclosure is achieved through the following technical solutions:

A manufacturing method of a circuit board, comprising:
forming an electroplated coating on a board body of the circuit board;
performing image transfer on the board body;
drilling the board body after the image transfer to remove a copper layer, adjacent to the two sides of the gold finger, on the circuit board, thereby forming a strip;
performing forward and reverse routing towards directions away from each other at the two sides of each gold finger respectively to form a first routing tape and a second routing tape, wherein the first routing tape and the second routing tape are connected to the two ends of the strip respectively;
and removing burrs on the surface of the board body through an etching process.

In one embodiment, entry directions for machining the first routing tape and the second routing tape are opposite, and feed directions for machining the first routing tape and the second routing tape are opposite.

In one embodiment, after the step of removing the burrs on the surface of the board body through the etching process, the manufacturing method further comprises:
performing a circuit etching process on the board body to obtain a copper surface circuit pattern on the surface of the circuit board.

In one embodiment, the step of performing forward and reverse routing towards the directions away from each other at the two sides of each gold finger respectively by adopting a router bit to form the first routing tape and the second routing tape specifically comprises:
performing forward and reverse routing towards the directions away from each other at the two sides of each gold finger respectively by adopting the router bit to form the first routing tape and the second routing tape.

In one embodiment, the router bit is a double-edged router bit.

In one embodiment, the step of performing forward and reverse routing towards the directions away from each other at the two sides of each gold finger respectively by adopting the router bit specifically comprises:
performing forward and reverse milling machining towards the directions away from each other at the two sides of each gold finger respectively by adopting the router bit.

In one embodiment, before the step of forming the electroplated coating on the board body of the circuit board, the manufacturing method further comprises:
performing electroless plating copper on the board body to form a first copper layer of the board body.

In one embodiment, the step of forming the electroplated coating on the board body of the circuit board specifically comprises:
forming the electroplated coating on the board body such that a second copper layer is formed on the surface of the first copper layer.

In one embodiment, before the step of performing the electroless plating copper on the board body to obtain the first copper layer of the board body, the manufacturing method further comprises:
performing hole routing machining on the board body to obtain plated through holes or plated through slots.

In one embodiment, before the step of performing hole routing machining on the board body, the manufacturing method further comprises:
performing a drilling operation on the board body.

A circuit board is obtained by machining using a manufacturing method of the circuit board provided by any embodiment of the present disclosure.

Compared to the prior art, the present disclosure at least has the following advantages:

1, an electroplated coating is formed on a board body of a circuit board at first; then image transfer is conducted on the board body to form an anti-etching mask pattern on a copper surface of the circuit board; then the board body after the image transfer is drilled to remove a copper layer, adjacent to the two sides of a gold finger, on the circuit board, thereby forming a strip; after that, forward and reverse routing are conducted towards directions away from each other at the two sides of each gold finger respectively to form a first routing tape and a second routing tape, wherein the first routing tape and the second routing tape are connected to the two ends of the strip respectively, and thus the machining directions of the first routing tape and the second routing tape are opposite; and finally, burrs on the surface of the board body are removed through an etching process, and the gold finger of the circuit board is machined;

2, due to the fact that the forward and reverse routing are conducted towards the directions away from each other at the two sides of each gold finger respectively, the first routing tape and the second routing tape are machined, that is, a reverse routing operation is added compared to the traditional process, and the drilling operation on the board body after the image transfer is added before routing to remove the copper layer, adjacent to the two sides of the gold finger, on the circuit board, thereby forming the strip; the first routing tape and the second routing tape are routed along the two ends of the strip, the problem that a copper sheet on the circuit board is warped in the machining process of the gold finger area is avoided, and the conductive property of the gold finger is improved.

### BRIEF DESCRIPTION OF THE DRAWINGS

To describe the technical solutions of the embodiments of the present disclosure more clearly, the accompanying drawings required to be used in the embodiments will be briefly introduced below. It should be understood that the following accompanying drawings illustrate only certain embodiments of the present disclosure and are therefore should not to be considered as limitation on scope. For those of ordinary skill in the art, other relevant accompanying drawings may also be obtained from these accompanying drawings without creative work.

FIG. 1 is a flow diagram of a manufacturing method of a circuit board of one embodiment.

### DETAILED DESCRIPTION OF THE EMBODIMENTS

To facilitate an understanding of the present disclosure, the present disclosure will be described more comprehensively below with reference to relevant accompanying drawings, and a preferred embodiment of the present disclosure is given in the accompanying drawings. The present disclosure, however, may be achieved in many different forms and is not limited to the embodiments described by the present disclosure. Instead, the purpose of providing these embodiments is to understand the disclosure of the present disclosure more thoroughly and completely.

It should be noted that when a component is called to be fixed to another component, the component may be directly fixed to the other component or a centered component may exist. When one component is regarded as to be connected to another component, the component may be directly connected to another component or a centered component may exist at the same time. Terms, such as perpendicular, horizontal, left, right, and like expressions, used herein are for illustrative purposes only, and are not meant to be the only embodiment.

Unless defined otherwise, all technical and scientific terms used herein have the same meaning as commonly understood by those skilled in the art to which the present disclosure belongs. The terminology used in the specification of the present disclosure herein is for the purpose of describing particular embodiments only and is not intended to limit the present disclosure. The term “and/or” used herein includes any combination and all combinations of one or more relevant listed items.

The present disclosure provides a manufacturing method of a circuit board, which comprises the steps of: forming an electroplated coating on a board body of the circuit board; performing image transfer on the board body; drilling the board body after the image transfer to remove a copper layer, adjacent to the two sides of the gold finger, on the circuit board, thereby forming a strip; performing forward and reverse routing towards directions away from each other at the two sides of each gold finger respectively to form a first routing tape and a second routing tape, wherein the first routing tape and the second routing tape are connected to the two ends of the strip respectively; and removing burrs on the surface of the board body through an etching process.

According to the manufacturing method of the circuit board provided by the present disclosure, an electroplated coating is formed on a board body of a circuit board at first; then image transfer is conducted on the board body to form an anti-etching mask pattern on a copper surface of the circuit board; then the board body after the image transfer is drilled to remove a copper layer, adjacent to the two sides of a gold finger, on the circuit board, thereby forming a strip; after that, forward and reverse routing are conducted towards directions away from each other at the two sides of each gold finger respectively to form a first routing tape and a second routing tape, wherein the first routing tape and the second routing tape are connected to the two ends of the strip respectively, and thus the machining directions of the first routing tape and the second routing tape are opposite; and finally, burrs on the surface of the board body are removed through an etching process, and the gold finger of the circuit board is machined; due to the fact that the forward and reverse routing are conducted towards the directions away from each other at the two sides of each gold finger respectively, the first routing tape and the second routing tape are machined, that is, a reverse routing operation is added compared to the traditional process, and the drilling operation on the board body after the image transfer is added before routing to remove the copper layer, adjacent to the two sides of the gold finger, on the circuit board, thereby forming the strip; the first routing tape and the second routing tape are routed along the two ends of the strip, the problem that a copper sheet on the circuit board is warped in the machining process of the gold finger area is avoided, and the conductive property of the gold finger is improved.

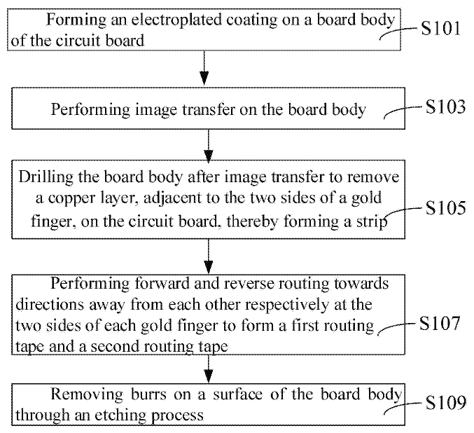

Please referring to FIG. 1, which is a flow diagram of a manufacturing method of a circuit board of one embodiment of the present disclosure.

The manufacturing method of the circuit board of one embodiment is used for preparing the circuit board, which comprises part or all of the following steps:

S101, Forming an electroplated coating on a board body of the circuit board.

In the embodiment, the electroplated coating is formed on the board body of the circuit board by using an electroplating process.

S103, Performing image transfer on the board body.

In the embodiment, the image transfer is conducted on the board body to form an anti-etching mask pattern on a copper surface of the circuit board.

S105, Drilling the board body after image transfer to remove a copper layer, adjacent to the two sides of a gold finger, on the circuit board, thereby forming a strip.

In the embodiment, the board body after image transfer is drilled to remove the copper layer, adjacent to the two sides of the gold finger, on the circuit board, namely, removing the copper layer surrounding the two sides of the gold finger, thereby forming the strip. Further, the strip extends in a semi-rectangular shape. In one embodiment, the step of drilling the board body after image transfer to remove the copper layer, adjacent to the two sides of the gold finger, on the circuit board specifically comprises: drilling the board body after image transfer by adopting drilling equipment, thereby removing the copper layer, adjacent to the two sides of the gold finger, on the circuit board.

S107, Performing forward and reverse routing towards directions away from each other at the two sides of each gold finger respectively to form a first routing tape and a second routing tape, wherein the first routing tape and the second routing tape are connected to the two ends of the strip respectively.

In the embodiment, the forward and reverse routing treatment are conducted towards the directions away from each other at the two sides of each gold finger respectively, that is, the forward and reverse routing are conducted towards the directions away from each other respectively from the two ends of the strip at the two sides of the gold finger, thereby machining to form the first routing tape and the second routing tape, and the first routing tape and the second routing tape are connected to the two ends of the strip respectively. Specifically, for two adjacent gold fingers, adjacent corresponding strips of the two gold fingers are connected through the first routing tape or the second routing tape, and therefore, the problem that a copper sheet is warped in the gold finger area may be better avoided. For example, there are three gold fingers which are a first gold finger, a second gold finger, and a third gold finger in sequence, the second routing tape adjacent to the first gold finger is connected to the first routing tape adjacent to the second gold finger, and the second routing tape adjacent to the second gold finger is connected to a third routing tape of a third gold finger. It may be understood that, in the embodiment, the first routing tape and the second routing tape may be machined successively, or may be machined simultaneously.

S109, Removing burrs on the surface of the board body through an etching process.

In the embodiment, the burrs on the surface of the board body are removed through the etching process to avoid the problem of existence of the burrs on the areas, such as the first routing tape, the second routing tape, the strip, and the like, adjacent to the gold finger, and thus the surface of the board body is smoother; and meanwhile, the problems of hurting people or short circuit and the like due to the existence of the burrs on the board body are avoided. In addition, the stress generated by the board body due to the burrs is avoided by removing the burrs on the surface of the board body.

According to the manufacturing method of the circuit board provided by the present disclosure, an electroplated coating is formed on a board body of a circuit board at first; then image transfer is conducted on the board body to form an anti-etching mask pattern on a copper surface of the circuit board; then the board body after the image transfer is drilled to remove a copper layer, adjacent to the two sides of a gold finger, on the circuit board, thereby forming a strip; after that, forward and reverse routing are conducted towards directions away from each other at the two sides of each gold finger respectively to form a first routing tape and a second routing tape, wherein the first routing tape and the second routing tape are connected to the two ends of the strip respectively, and thus the machining directions of the first routing tape and the second routing tape are opposite; and finally, burrs on the surface of the board body are removed through an etching process, and the gold finger of the circuit board is machined; due to the fact that the forward and reverse routing are conducted towards the directions away from each other at the two sides of each gold finger respectively, the first routing tape and the second routing tape are machined, that is, a reverse routing operation is added compared to the traditional process, and the drilling operation on the board body after the image transfer is added before routing to remove the copper layer, adjacent to the two sides of the gold finger, on the circuit board, thereby forming the strip; the first routing tape and the second routing tape are routed along the two ends of the strip, the problem that a copper sheet on the circuit board is warped in the machining process of the gold finger area is avoided, and the conductive property of the gold finger is improved.

To avoid mistaken drilling on a tin layer of the gold finger during drilling, in one embodiment, before the step of drilling the board body after image transfer, the manufacturing method further comprises the steps of: reserving a machining gap in a portion, where the strip is machined, on the circuit board, and even if the drilling equipment is in the drilling process, the gold finger may be avoided when drilling the board body after image transfer, and mistaken drilling on the tin layer of the gold finger during drilling is avoided. In one embodiment, the machining gap is 0.1 mm to 0.5 mm, which may better avoid the problem of mistakenly drilling the tin layer of the gold finger during drilling.

To make the gold finger meet dimensional requirements better, further, the tolerance of a width of the gold finger is −0.2 mm to 0.1 mm, which makes the gold finger meet the dimensional requirements better. Specifically, the tolerance of the width of the gold finger is −0.2 mm to 0.1 mm, and the tolerance of a height is 0 to 0.3 mm, and thus the gold finger may meet the dimensional requirements better.

In one embodiment, entry directions for machining the first routing tape and the second routing tape are opposite, and feed directions for machining the first routing tape and the second routing tape are opposite, thereby performing forward and reverse routing towards directions away from each other respectively at the two sides of each gold finger and avoiding the problem that the board edge is warped better. In the embodiment, the entry directions for machining the first routing tape and the second routing tape are opposite, i.e., the directions away from the gold finger respectively at the two sides of the same gold finger are served as the entry directions for machining the first routing tape and the second routing tape. Specifically, the feed direction for machining the first routing tape and the feed direction for machining the second routing tape are opposite, and the feed direction for machining the first routing tape and the feed direction for machining the second routing tape are same as an extending direction of the gold finger respectively.

In one embodiment, after the step of removing the burrs on the surface of the board body through the etching process, the manufacturing method further comprises:
performing a circuit etching process on the board body to obtain a copper surface circuit pattern on the surface of the circuit board.

In the embodiment, after the step of removing the burrs on the surface of the board body through the etching process, the circuit etching process is further conducted to the board body to obtain the copper surface circuit pattern of the surface of the board body, and meanwhile, the circuit etching process is further conducted to the board body after the gold finger is formed, which makes the circuit etching process simpler.

In one embodiment, the step of performing forward and reverse routing towards the directions away from each other respectively at the two sides of each gold finger to form the first routing tape and the second routing tape specifically comprises:
performing forward and reverse routing towards the directions away from each other respectively at the two sides of each gold finger by adopting a router bit, thereby forming the first routing tape and the second routing tape.

In the embodiment, a semi-slot is formed between two adjacent gold fingers, two strips which are parallel to each other are formed in the semi-slot, and each strip is adjacent to the corresponding gold finger. The router bit routes into a copper layer in the semi-slot along an extending direction parallel to the gold finger, performs milling entry in the forward and reverse rotating manner respectively, and performs milling feed towards directions opposite to the directions away from the gold finger from each other.

In one embodiment, the router bit is a double-edged router bit, and thus the same router bit may be suitable for simultaneously machining the first routing tape and the second routing tape, the adaptability of the router bit is improved, and meanwhile, the problem that the copper sheet is warped after the first routing tape and the second routing tape are machined by the router bit may be avoided. Due to the fact that the router bit may perform cutting machining in the forward and reverse rotating manner on the board body without changing a tool during cutting machining, the machining efficiency of the circuit board is greatly improved. In addition, compared with the traditional adoption of a fish scale-type router bit, the double-edged router bit is stronger and has better cutting force, and the copper sheet may be easily cut off and may not be warped during the routing of the router bit, thereby guaranteeing basic consistence of the lengths of the copper sheets at the left side and the right side of the gold finger, and meanwhile, the router bit is prevented from routing into the gold finger.

In one embodiment, the step of performing forward and reverse routing towards the directions away from each other respectively at the two side of each gold finger by adopting the router bit specifically comprises: performing forward and reverse milling machining towards the directions away from each other at the two sides of each gold finger by adopting the router bit.

In the embodiment, the forward and reverse milling machining are conducted towards the directions away from each other at the two sides of each gold finger by adopting the router bit. Specifically, a milling entry way of the router bit at the two sides of each gold finger is rotary entry, i.e., spiral entry; the rotary entry is conducted by adopting a forward rotary milling way when machining the first routing tape, that is, the spiral milling entry in a clockwise direction is adopted. While the rotary entry is conducted by adopting a reverse rotary milling way when machining the second routing tape, that is, the spiral milling entry in a counter-clockwise direction is adopted. Therefore, the entry directions of the router bit are different when machining the first routing tape and the second routing tape.

In one embodiment, a milling engage way of the router bit at the two sides of each gold finger is linear engage, and engage directions for machining the first routing tape and the second routing tape are opposite. Wherein, the forward linear engage way is adopted for the engage when machining the first routing tape, and the reverse linear engage way is adopted for the engage when machining the second routing tape. That is, when machining the first routing tape and the second routing tape, the engage directions are both linear engage, but the directions of the linear engage are opposite. In the process that the router bit machines the first routing tape by engaging along the forward linear engage way, the router bit rotates clockwise in the engage direction. In the process that the router bit machines the second routing tape by engaging along the reverse linear engage way, the router bit rotates counter-clockwise in the engage direction.

Further, the router bit comprises a tool holder and a plurality of cutting portions, the plurality of cutting portions are distributed in a spaced manner along a circumferential direction of the tool holder. In the embodiment, the spacing between every two adjacent cutting portions is equal, the plurality of the cutting portions uniformly cut the circuit board in the process of rotating along with the tool holder, thereby making the router bit have a better machining effect on the circuit board. In one embodiment, each cutting portion is detachably connected to the tool holder, each cutting portion may be periodically maintained or replaced, the use cost of the router bit is reduced, and the use convenience of the router bit is improved at the same time. Further, the tool holder comprises a main shaft, a mounting frame nested on the main shaft, and a plurality of locking pieces; a plurality mounting notches and a plurality of first fixing holes are formed in the mounting frame, and the plurality of mounting notches are communicated with the plurality of first fixing holes in a one-to-one correspondence manner. Each cutting portion is clamped into one corresponding mounting notch, and a second fixing hole corresponding to the corresponding first fixing hole is formed in each cutting portion, each locking piece is arranged in the corresponding first fixing hole and the second fixing hole in a penetrating manner, and thus each cutting portion is fixedly mounted on the mounting frame of the main shaft.

To make the cutting portion be firstly clamped to the mounting notch, further, the mounting notch extends in a contracted manner, and the notch width of the mounting notch is greater than the bottom width of the mounting notch, and therefore the cutting portion is clamped to the mounting notch in an interference fit manner, and the cutting portion is firmly clamped to the mounting notch.

To avoid the situation of shaking when the cutting portion is clamped to the mounting notch, further, at least two oppositely arranged auxiliary clamping ribs are convexly arranged on the edge, provided with the mounting notch, of the mounting frame, and the at least two auxiliary clamping ribs are propped against two side faces of the cutting portion respectively; when the cutting portion is clamped into the mounting notch, the auxiliary clamping ribs are propped against the cutting portion, and thus the cutting portion may be mounted on the mounting frame more reliably. Further, the auxiliary clamping ribs are elastic ribs and are bent, the two oppositely arranged auxiliary clamping ribs are bent in directions close to each other, and thus the two auxiliary clamping ribs may be elastically propped against the two side faces of the cutting portions better.

It may be understood that in order to better meet the router bit for milling the circuit board at high speed, in other embodiments, the auxiliary clamping rib is not limited to elastic rib. In one embodiment, the auxiliary clamping rib comprises an auxiliary clamping frame and an elastic rubber layer arranged on the auxiliary clamping frame, the auxiliary clamping frame is connected to the cutting portion, and the strength of the auxiliary clamping frame is the same as that of the cutting portion; the elastic rubber layer is elastically propped against the cutting portion, which not only may avoid situation of shaking when the cutting portion is clamped to the mounting notch, but also improve the strength of the auxiliary clamping rib. In the embodiment, the elastic rubber layer is glued on the auxiliary clamping frame, and thus the elastic rubber layer is firmly connected to the auxiliary clamping frame. However, when the auxiliary clamping rib and the cutting portion are repeatedly dismounted, the elastic rubber layer is prone to being worn to affect an effect of propping against the cutting portion, and in other embodiments, the elastic rubber layer is not only limited to be glued on the auxiliary clamping frame. In one embodiment, a plug slot is formed in one face, adjacent to the cutting portion, of the auxiliary clamping frame, and the elastic rubber layer is plugged into the plug slot and elastically propped against the auxiliary clamping frame.

To make the auxiliary clamping rib be propped against the cutting portion reliably, further, a locating slot adapted to the auxiliary clamping rib is formed in the cutting portion, the auxiliary clamping rib is propped against the inner wall of the locating slot, and thus the auxiliary clamping rib is propped against the cutting portion reliably.

Certainly, to make the cutting portion be firmly connected to the tool holder, in other embodiments, each cutting portion may also be connected to the tool holder in a non-detachable manner. In one embodiment, each cutting portion is welded to the tool holder, and thus each cutting portion is firmly connected to the tool holder, and the router bit has higher strength at the same time. In another embodiment, the tool holder and the plurality of cutting portions are integrally formed, and thus each cutting portion is firmly connected to the tool holder, and meanwhile, the router bit has higher strength and is more compact in structure.

Further, each cutting portion is provided with a first cutting edge and a second cutting edge which are oppositely arranged, and one end of the first cutting edge is connected to one end of the second cutting edge to form a cutting edge point of the cutting portion. In the embodiment, the outline of the first cutting edge and the outline of the second cutting edge are both arc-shaped, and the radian of the outline of the first cutting edge is different from that of the outline of the second cutting edge. When the router bit rotates in a forward direction, the first cutting edge cuts and acts on the board body. When the router bit rotates in a reverse direction, the second cutting edge cuts and acts on the board body. Therefore, for the same router bit, the first routing tape and the second routing tape may be cut and machined in the forward direction and the reverse direction respectively without tool changing during machining, and the machining efficiency of the circuit board is improved. Specifically, when the first routing tape is machined, the tool holder rotates in the forward direction to make the first cutting edge act on the board body. When the second routing tape is machined, the tool holder rotates in the reverse direction to make the second cutting edge act on the board body. Therefore, the router bit may cut and machine the board body in the forward and reverse rotation manner without tool changing in the machining, and the machining efficiency of the circuit board is greatly improved.

To make the router bit cut the board body better, further, an extending direction, in which the first cutting edge is connected to an end portion of the second cutting edge, is a first direction, an extending direction, in which the second cutting edge is connected to the end portion of the first cutting edge, is a second direction, an included angle between the first direction and the second direction is 75-90 degrees, and thus the router bit may cut the board body better. In the embodiment, the included angle between the first direction and the second direction is 82 degrees, and thus the router bit may cut the board body better.

In one embodiment, before the step of forming the electroplated coating on the board body of the circuit board, the manufacturing method further comprises:
performing electroless plating copper on the board body to obtain a first copper layer of the board body, and thus making the electroplated coating be formed on the surface of the first copper layer.

Further, the step of forming the electroplated coating on the board body such that a second copper layer is formed on the surface of the first copper layer specifically comprises: forming the electroplated coating on the board body by adopting a panel plating process. In one embodiment, the step of forming the electroplated coating on the board body of the circuit body specifically comprises: forming the electroplated coating on the board body to form the second copper layer on the surface of the first copper layer, and thus forming the second copper layer on the surface of the first copper.

In one embodiment, before the step of performing the electroless plating copper on the board body to obtain the first copper layer of the board body, the manufacturing method further comprises: performing hole routing machining on the board body to obtain plated through holes or plated through slots.

In one embodiment, before the step of performing hole routing machining on the board body, the manufacturing method further comprises: performing a drilling operation on the board body.

Further, after the step of removing the burrs on the surface of the board body through the etching process, the manufacturing method of the circuit board further comprises:
performing character handling on the board body to print a character mark and a cutting alignment line on the board body, wherein the cutting alignment line passes through the center of the metal hole. In the embodiment, the character mark may be a resistance or capacitance character or a positive or negative electrode character or the like. A plurality of cutting alignment lines are provided, and the plurality of cutting alignment lines are distributed in a grid shape. The plurality of cutting alignment lines comprise M transverse cutting alignment lines and N vertical cutting alignment lines, the M transverse cutting alignment lines are arranged side by side, the N vertical cutting alignment lines are arranged side by side, there are intersections between each transverse cutting alignment line and the N vertical cutting alignment lines respectively, and there are intersections between each longitudinal cut alignment and the M vertical cutting alignment lines respectively. Every two adjacent sub-boards are demarcated through one cutting alignment line. The cutting alignment line passes through the center of the metal hole, that is, the cutting alignment line between two adjacent sub-boards passes through the center of the metal hole between two adjacent sub-boards, that is, the cutting alignment line between two adjacent sub-boards passes through the center of the metal hole between two adjacent sub-boards.

Further, the manufacturing method further comprises: identifying the cutting alignment line of the board body; predrilling the periphery of the metal hole of the board body according to the cutting alignment line, thus machining a pre-drilled hole on the board body, wherein the cutting alignment line also passes through the center of the pre-drilled hole; and performing V-cut board separation on the tested board along the cutting alignment line.

In the embodiment, the identification of the cutting alignment line of the board body is the process of capturing the cutting alignment line of the board body. It may be understood that the cutting alignment line of the board body may be identified by human eyes or collected and identified by a machine, for example, a CCD camera or a CMOS camera is adopted for collecting and identifying the cutting alignment line of the board body. According to the cutting alignment line, the periphery of the metal hole of the board is pre-drilled, that is, pre-drilling is conducted at the intersections of the cutting alignment line and the periphery of the metal hole, that is, pre-drilled holes are machined in the two end points, intersected to the periphery of the metal hole, of the center of the metal hole passing through the cutting alignment line respectively; and therefore, two symmetrical pre-drilled holes are machined in the periphery of each metal hole. V-cut board separation is conducted on the tested board along the cutting alignment line to obtain at least two sub-boards.

Due to the fact that the pre-drilled holes are machined in the board body before board separation, that is, the metal hole and the holes in contact with a V-cut path are drilled out before V-cut, copper is prevented from being pulled out in the V-cut process, the surface of the sub-board obtained after V-cut is smoother, and the production efficiency of the circuit board is improved; due to the fact that the step of performing V-cut board separation on the tested board along the cutting alignment line is located after the step of performing character handling on the board body, the step of performing V-cut board separation on the tested board along the cutting alignment line is designed after the etching process, and the problem of low production efficiency of the circuit board caused by a cross-procedure production procedure adopted by a traditional circuit board manufacturing method is avoided. The board separation operation is added to the production procedure of the circuit board, the problem of expansion and shrinkage in the subsequent transportation process does not need to be considered, the board separation is conducted according to the cutting alignment line, and thus the circuit board obtained through machining is more accurate.

In one embodiment, a plurality of metal holes are provided on the same cutting alignment line, and the plurality of metal holes are arranged side by side. In the embodiment, a plurality of metal holes are provided on the same cutting alignment line, that is, a plurality metal holes are formed in a boundary between two adjacent sub-boards.

In one embodiment, two pre-drilled holes are formed in the periphery of the same metal hole, that is, the pre-drilled holes are formed in the two end points, intersected to the periphery of the metal hole, of the center of the metal hole passing through the cutting alignment line respectively, and therefore two symmetrical pre-drilled holes are machined in the periphery of each metal hole. Pre-drilled holes are formed in the intersections of the metal hole and the cutting alignment line, the situation that copper sheet is rolled up in the process of performing V-cut board separation along the cutting alignment lines is avoided, and the situation that metal burrs exist on the cutting line between the sub-boards is avoided.

To improve the smoothness of separating the board body into the sub-boards, in one embodiment, the diameter of the pre-drilled hole is equal to 0.2 of the diameter of the metal hole, the metal hole and the pre-drilled hole are drilled out before performing the V-cut on the board body, the situation that the copper layer is pulled in the V-cut process of the board body is effectively avoided, and the smoothness of separating the board body into the sub-boards is improved.

In one embodiment, before the step of performing V-cut board separation on the tested board along the cutting alignment line, and after the step of performing large board test on the board body, the manufacturing method further comprises:
performing second drilling on the metal hole of the board body to mill and remove debris in the metal hole. Due to the fact that the debris such as copper debris exist on the inner wall of the metal hole after the metal hole is machined and formed, if the debris are not cleaned in advance, burrs may exist on the surface of the metal semi-hole obtained after V-cut, the appearance of the metal semi-hole is affected, and thus the percent of pass of the sub-board of the circuit board is low.

In one embodiment, the step of performing V-cut board separation on the tested board along the cutting alignment line specifically comprises:
performing V-cut board separation on the tested board along the cutting alignment line through a V-cut separator. In the embodiment, the V-cut board separation is conducted on the tested board along the cutting alignment line through the V-cut separator, thereby separating the board into at least two sub-boards, namely, at least two sub-boards of the circuit board.

In one embodiment, the V-cut separator comprises a main rack, a first movable frame, a second movable frame, a first cutting assembly, and a second cutting assembly; the first movable frame and the second movable frame are movably arranged on the main rack, the first cutting assembly is arranged at the first movable frame, the second cutting assembly is arranged at the second movable frame, and the first cutting assembly and the second cutting assembly are oppositely arranged. The first movable frame and the second movable frame move relative to each other, that is, the first movable frame and the second movable frame get close to each other or get away from each other, which makes the first cutting assembly and the second cutting assembly get close to each other or get away from each other, and then the first cutting assembly and the second cutting assembly cut the sub-board of the circuit board along the cutting alignment line together, and the V-cut board separation of the board body is achieved. In the embodiment, the first cutting assembly and the second cutting assembly are used for cutting the large board along the cutting alignment line from the two sides of the large board respectively, and thus the sub-boards are effectively separated along the cutting alignment line, and a cutting plane of the first cutting assembly for the large plate and the cutting plane of the second cutting assembly for the large board are on the same cutting plane; and the separation plane between the sub-boards is smooth.

Further, the V-cut separator further comprises a driving assembly, the driving assembly is arranged on the main rack, and the power output end of the driving assembly is connected to the first movable frame and the second movable frame respectively, and thus the driving assembly drives the first movable frame and the second movable frame to get close to or away from each other, thereby adjusting the distance between the first cutting assembly and the second cutting assembly, and different processing requirements of the sub-board of the circuit board are achieved. In the embodiment, the first cutting assembly and the second cutting assembly both conduct one-time cutting to achieve board separation, and then the driving assembly drives the first movable frame and the second movable frame to get close to each other till the distance between the first cutting assembly and the second cutting assembly on the machining surface is zero. The driving assembly is a double-cylinder driving assembly, the power output end of the driving assembly comprises a first end and a second end, a power output direction of the first end is close to or far away from a power output direction of the second end, the first movable frame is connected to the first end, and the second movable frame is connected to the second end.

Further, a first sliding chute and a second sliding chute are formed in the main rack, and an extending direction of the first sliding chute and an extending direction of the second sliding chute are collinear. The first movable frame comprises a first frame body and a first sliding block which are connected, the first frame body is connected to the power output end of the driving assembly, and the first frame body is located in the first sliding chute and slidingly connected to the main rack. The first cutting assembly is fixedly mounted on the first frame body, and thus the first cutting assembly is arranged on the first movable frame. The second movable frame comprises a second frame body and a second sliding block which are connected, the second frame body is connected to the power output end of the driving assembly, and the second frame body is located in the second sliding chute and slidably connected to the main rack. The second cutting assembly is fixedly mounted on the second frame body, and thus the second cutting assembly is arranged on the second movable frame.

Further, the first cutting assembly comprises a first tool holder, a first rotary tool body, a first transmission assembly, and a first power source, the first tool holder is rotationally arranged on the first frame body, the first rotary tool body is fixed to the first tool holder, and the first power source is arranged on the first frame body. The first power source drives the first tool holder to rotate relative to the first frame body through the first transmission assembly. In the embodiment, the first tool holder is nested on the first frame body through a bearing, and thus the rotation of the first tool holder and the first frame body is more stable and the wear resistance is less. The first transmission assembly comprises a first gear and a second gear, the first gear is nested on an output shaft of the first power source, the second gear is nested on the first tool holder, and the second gear and the first gear are in meshing transmission. The first power source is a motor or a rotary cylinder. The first rotary tool body and the first tool holder are coaxially arranged.

Further, the first rotary tool body comprises a first tool pan and a plurality of first cutting edges, the first tool pan is fixed to the first tool holder, the plurality of first cutting edges are distributed along the circumferential direction of the first tool pan in a spaced manner, the outline of each first cutting edge is in a V shape, and thus the first rotary tool body may perform V-cut machining on a large board of the circuit board. In the embodiment, the first tool pan is fixed to the first tool holder, and the first tool pan and the plurality of first cutting edges are integrally formed. In other embodiments, the first tool pan and the plurality of first cutting edges may also be formed individually and fixedly connected by welding.

Further, the second cutting assembly comprises a second tool holder, a second rotary tool body, a second transmission assembly, and a second power source, the second tool holder is rotationally arranged on the second frame body, the second rotary tool body is fixed to the second tool holder, and the second power source is arranged on the second frame body. The second power source drives the second tool holder to rotate relative to the second frame body through the second transmission assembly. In the embodiment, the second tool holder is nested on the second frame body through a bearing, and thus the rotation of the second tool holder and the second frame body is more stable and the wear resistance is less. The second transmission assembly comprises a third gear and a fourth gear, the third gear is nested on an output shaft of the second power source, the fourth gear is nested on the second tool holder, and the fourth gear and the third gear are in meshing transmission. The second power source is a motor or a rotary cylinder. The second rotary tool body and the second tool holder are coaxially arranged.

Further, the second rotary tool body comprises a second tool pan and a plurality of second cutting edges, the second tool pan is fixed to the second tool holder, the plurality of second cutting edges are distributed along the circumferential direction of the second tool pan in a spaced manner, the outline of each second cutting edge is in a V shape, and thus the second rotary tool body may perform V-cut machining on a large board of the circuit board. In the embodiment, the second tool pan is fixed to the second tool holder, and the second tool pan and the plurality of second cutting edges are integrally formed. In other embodiments, the second tool pan and the plurality of second cutting edges may also be formed individually and fixedly connected by welding.

In one embodiment, the V-cut separator further comprises a bearing lifting mechanism which is arranged on the main rack. The bearing lifting mechanism comprises a lifting assembly, a bearing main plate, and a plurality of supporting adsorption pieces; the lifting assembly is mounted on the main rack, the bearing mainboard is connected to the power output end of the lifting assembly, and the lifting assembly drives the bearing main plate to ascend and descend relative to the main rack. The plurality of supporting adsorption pieces are connected to the side, away from the power output end of the lifting assembly, of the bearing main plate. The plurality of supporting adsorption pieces are arranged in a spaced manner, each supporting adsorption piece comprises a supporting shaft and a sucker, one end of each supporting shaft is connected to the bearing main plate, and each sucker is arranged at the other end of the corresponding supporting shaft. The suckers of the plurality of supporting adsorption pieces are adsorbed to the corresponding sub-boards, and thus each supporting adsorption piece supports and fixes the corresponding sub-board. The lifting assembly drives the bearing main plate to ascend and descend relative to the main rack before performing V-cut board separation, and thus the suckers of the supporting suction pieces are propped against and adsorbed to the sub-boards, the sub-boards are relatively located before separation, and the problem that part of the sub-boards fall off after the V-cut board separation is solved. Further, the bearing main plate is slidingly connected to the main rack. The lifting assembly comprises a lifting motor, a lead screw, and a nut, the lifting motor is fixedly mounted on the main rack, one end of the lead screw is connected to a power shaft of the lifting motor, the other end of the lead screw is rotationally connected to the main rack, and the nut is connected to the bearing main plate. When the lifting motor drives the lead screw to rotate relative to the main rack, the lead screw drives the nut to be in thread transmission, and thus the bearing main plate is slidingly connected to the main rack. It may be understood that the suckers are adsorbed to the surfaces of the sub-boards when the sub-boards are supported, fixed, and located. When the sub-boards need to be loosened, the suckers blow air to loosen the surfaces of the sub-boards.

In one specific embodiment, two V cutters of the V-cut separator are in a front-back direction, that is, the spacing between the first cutting edge and the second cutting edge of the V-cut separator is small, the residual thickness of cutting of the sub-board is set to be 0, thereby achieving one-time cutting of the first cutting edge and the second cutting edge, that is, the separation between the sub-boards is achieved; the V-cut is free of chamfers; and as V cutter teeth completely penetrate into the board, the two sides of the V cut are flush. When the residual thickness is 0, the board is in completely cut in a V shape, the boards are directly separated to obtain corresponding sub-boards, and the sub-boards are directly welded to a motherboard; an operation of performing board separation through board separation equipment is not needed, the unnecessary flow is reduced, and the production efficiency of a factory is improved; and meanwhile, there are two semi-holes on the designed sub-board, and the utilization rate of a board material is greatly improved due to the design that the two semi-holes are not formed by dividing double hole, the number of the designed drilled hole is reduced, the production efficiency is improved by reducing the number of the drilled hole, and the cost is reduced.

The present disclosure further provides a circuit board, which is obtained by machining using a manufacturing method of the circuit board of any embodiment.

Compared with the prior art, the present disclosure at least has the following advantages:

1, an electroplated coating is formed on a board body of a circuit board at first; then image transfer is conducted on the board body to form an anti-etching mask pattern on a copper surface of the circuit board; then the board body after the image transfer is drilled to remove a copper layer, adjacent to, the two sides of a gold finger, on the circuit board, thereby forming a strip; after that, forward and reverse routing are conducted towards directions away from each other at the two sides of each gold finger respectively to form a first routing tape and a second routing tape, wherein the first routing tape and the second routing tape are connected to the two ends of the strip respectively, and thus the machining directions of the first routing tape and the second routing tape are opposite; and finally, burrs on the surface of the board body are removed through an etching process, and the gold finger of the circuit board is machined:

2, due to the fact that the forward and reverse routing are conducted towards the directions away from each other at the two sides of each gold finger respectively, the first routing tape and the second routing tape are machined, that is, a reverse routing operation is added compared to the traditional process, and the drilling operation on the board body after the image transfer is added before routing to, remove the copper layer, adjacent to the two sides of the gold finger, on the circuit board, thereby forming the strip; the first routing tape and the second routing tape are routed along the two ends of the strip, the problem that a copper sheet on the circuit board is warped in the machining process of the gold finger area is avoided, and the conductive property of the gold finger is improved.

The above-mentioned embodiments are merely illustrative of several embodiments of the present disclosure, and the description thereof is more specific and detailed, but is not to be construed as limiting the scope of the present disclosure. It should be noted that many variations and modifications may be made by those of ordinary skill in the art without departing from the spirit and scope of the present disclosure, all of which fall within the scope of protection of the present disclosure. Therefore, the scope of protection of the present disclosure should be determined by the appended claims.

What is claimed is:

1. A manufacturing method of a circuit board, comprising:
forming an electroplated coating on a board body of the circuit board;
performing image transfer on the board body;
drilling the board body after image transfer to remove a copper layer, adjacent to the two sides of a gold finger, on the circuit board, thereby forming a strip;
performing forward and reverse routing towards directions away from each other respectively at the two sides of each gold finger to form a first routing tape and a second routing tape, wherein the first routing tape and the second routing tape are connected to the two ends of the strip respectively;
and removing burrs on a surface of the board body through an etching process.

2. The manufacturing method of the circuit board according to claim 1, wherein entry directions for machining the first routing tape and the second routing tape are opposite, and feed directions for machining the first routing tape and the second routing tape are opposite.

3. The manufacturing method of the circuit board according to claim 1, wherein, after the step of removing the burrs on the surface of the board body through the etching process, the manufacturing method further comprises:
performing a circuit etching process on the board body to obtain a copper surface circuit pattern on the surface of the circuit board.

4. The manufacturing method of the circuit board according to claim 1, wherein the step of preforming forward and reverse routing towards the directions away from each other respectively at the two sides of each gold finger to form the first routing tape and the second routing tape specifically comprises:
performing forward and reverse routing towards the directions away from each other respectively at the two sides of each gold finger by adopting a router bit, thereby forming the first routing tape and the second routing tape; the router bit being a double-edged router bit.

5. The manufacturing method of the circuit board according to claim 3, wherein the step of performing forward and reverse routing towards the directions away from each other respectively at the two sides of each gold finger by adopting the router bit specifically comprises:
performing forward and reverse milling machining towards the directions away from each other respectively at the two sides of each gold finger by adopting the router bit.

6. The manufacturing method of the circuit board according to claim 1, wherein, before the step of forming the electroplated coating on the board body of the circuit board, the manufacturing method further comprises:
performing electroless plating copper on the board body to obtain a first copper layer of the board body.

7. The manufacturing method of the circuit board according to claim 6, wherein the step of forming the electroplated coating on the board body of the circuit board specifically comprises:
forming the electroplated coating on the board body such that a second copper layer is formed on the surface of the first copper layer.

8. The manufacturing method of the circuit board according to claim 6, wherein, before the step of performing electroless plating copper on the board body to obtain the first copper layer of the board body, the manufacturing method further comprises:
performing hole routing machining on the board body to obtained a plated through hole or a plated through slot on the board body.

9. The manufacturing method of the circuit board according to claim 8, wherein, before the step of performing hole routing machining on the board body, the manufacturing method further comprises:
performing a drilling operation on the board body.

10. A circuit board, which is obtained by machining using the manufacturing method of the circuit board according to claim 1.
